(19) United States
(12) Patent Application Publication
(10) Pub. No.: US 2021/0029461 A1
(43) Pub. Date: Jan. 28, 2021

(54) Heat dissipation device

(71) Applicant: AAC Technologies Pte. Ltd., Singapore city (SG)

(72) Inventors: Xingzhi Huang, Shenzhen (CN); Lin Liu, Shenzhen (CN); Dijiang Tong, Shenzhen (CN); Zhe Zhang, Shenzhen (CN); Jun Wu, Shenzhen (CN); Zhichen Chen, Shenzhen (CN); Zhaoyu Yin, Shenzhen (CN)

(21) Appl. No.: 16/995,844

(22) Filed: Aug. 18, 2020

Related U.S. Application Data
(63) Continuation of application No. PCT/CN2019/097763, filed on Jul. 25, 2019.

(30) Foreign Application Priority Data
Jul. 22, 2019 (CN) 201921159899.6

(51) Int. Cl. H04R 9/02; H04R 1/02; H04R 9/06; H05K 7/20; H04R 7/02

(52) U.S. Cl. CPC H04R 9/022; H04R 1/02; H04R 7/02; H05K 7/2039; H04R 9/06

(57) ABSTRACT

The invention relates to a heat dissipation device having a heating element and a speaker assembly. The speaker assembly includes a housing having an accommodation space and a speaker unit installed in the accommodation space. The heat dissipation device also comprises a heat conductor; the heat conductor comprises a first end part, a second end part connected to the heating element and a connection part connecting the first end part and the second end part. The heat conductor is used to introduce the heat generated by the heating element to the speaker assembly and transfer it to the outside. The heat dissipation device has a better heat dissipation effect.

### FIELD OF THE PRESENT DISCLOSURE

The invention relates to the heat dissipation technologies, in particular to a heat dissipation device using a speaker box with a diaphragm.

### DESCRIPTION OF RELATED ART

People often use electronic devices with heat dissipation function, such as mobile phones, computers and so on, the devices can emit sound, but the components inside will emit heat in the course of use. With the operation time extension of heat dissipation device, the temperature of the device will be higher and higher. Too high temperature will affect the performance of the device and reduce the life thereof. However, existing technologies do not have effective solutions to lower the temperature of the device.

### SUMMARY OF THE INVENTION

One of the main objects of the invention is to provide a heat dissipation device with improved heat dissipation efficiency.

Accordingly, the present invention provides a heat dissipation device comprising:

a heating element; and

a speaker assembly comprising a housing having an accommodation space, and a speaker unit installed in the accommodation space and comprising a vibration system and a magnetic circuit system that drives the vibration system to vibrate; at least part of one side of the magnetic circuit system away from the vibration system exposed at the housing via an opening in the housing; the vibration system separating the accommodation space into a front cavity and a back cavity;

a sound outlet hole arranged in the housing for connecting the front cavity and outside;

a heat conductor comprising a first end part fixed to a side of the magnetic circuit system away from the vibration system, a second end part connected to the heating element, a connection part connecting the first end part and the second end part, for introducing the heat generated by the heating element to the speaker assembly and then transfer to the outside of the sound outlet hole with air in the front cavity.

Further, the housing comprises a top wall arranged opposite to the vibration system, a bottom wall fixed to the magnetic circuit system, and a side wall bending and extending from the edge of the top wall to a direction close to the bottom wall; the top wall, the side wall and the bottom wall enclose to form the accommodation space; the opening is arranged on the bottom wall; the housing further comprises a support wall extending from the top wall into the accommodation space and supporting the speaker unit.

Further, the magnetic circuit system comprises a yoke and a magnet assembly fixed to one side of the yoke near the vibration system, at least part of the yoke is arranged exposed at the bottom wall via the opening.

Further, an outer surface of the yoke and an outer surface of the bottom wall are coplanar, and one side of the connection part near the first end part is fixedly connected to the outer surfaces of the housing.

Further, the sound outlet hole is arranged on the side wall, and the housing further comprises a baffle wall extending from the side wall toward the speaker unit, a sound channel is enclosed and formed between the baffle wall and the top wall as well as the side wall; the vibration system comprises a diaphragm, and the front acoustic cavity is formed between the diaphragm and the top wall directly facing the diaphragm; the front cavity comprises the front acoustic cavity and the sound channel, the sound channel communicates the front acoustic cavity with the sound outlet hole.

Further, the housing further comprises a metal embedding member embedded in the top wall, the metal embedding member is directly facing the diaphragm and integrally formed with the top wall by injection molding.

Further, the heat dissipation device further comprises a chassis, the chassis comprises a bottom plate arranged opposite to the bottom wall and a side panel bending and extending from the edge of the bottom plate, the first end part is sandwiched between the bottom plate and the speaker assembly, the side panel is attached to one side of the side wall correspondingly arranged with the sound outlet hole, the side panel is correspondingly arranged with a through hole communicating the sound outlet hole and the outside.

Further, the heat conductor further comprises an extension part extending from the first end part toward the side panel, the side of the extension part away from the first end part is embedded in the side panel.

Further, the bottom plate and the side panel are integrally formed.

Further, the heat conductor is a heat conducting tube or a solid metal conductor with a condensed liquid inside.

Further, the heat conductor is strip-shaped, and the width of the first end part is larger than the width of other parts of the heat conductor.

### BRIEF DESCRIPTION OF THE DRAWINGS

Many aspects of the exemplary embodiment can be better understood with reference to the following drawings. The components in the drawing are not necessarily drawn to scale, the emphasis instead being placed upon clearly illustrating the principles of the present disclosure.

FIG. 1 is a partial isometric view of a heat dissipation device provided by an embodiment of the present invention.

FIG. 2 is a partial exploded view of the heat dissipation device provided by the embodiment of the invention.

FIG. 3A is an isometric view of a speaker assembly provided by the embodiment of the present invention.

FIG. 3B is an exploded view of a speaker assembly provided by the embodiment of the present invention.

FIG. 4A is an isometric view of a speaker unit provided by the embodiment of the present invention.

FIG. 4B is a cross-sectional view of the speaker unit provided by the embodiment of the present invention.

FIG. 5A is a cross-sectional view taken along line A-A in FIG. 1.

FIG. 5B is an enlarged view of part B in FIG. 5A.

FIG. 6A is an exploded view of a housing provided by the embodiment of the present invention, from a first aspect.

FIG. 6B is an exploded view of the housing provided by the embodiment of the present invention, from a second aspect.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

The terms “first”, “second”, “third”, “fourth” and the like (if any) in the description, claims and the above drawings of the present application are used to distinguish similar objects, and need not be used to describe specific order or sequence. It should be understood that the data so used can be interchanged at appropriate situation so that the embodiment described herein can be implemented in an order other than what is illustrated or described here. In addition, the terms “include” and “have” and any of their variations are intended to cover non-exclusive inclusion, for example, a process, method, system, product or device that contains a series of steps or units need not be limited to those steps or units that are clearly listed, but may include those that are not clearly listed or for those processes, methods, products Other steps or units inherent in products or equipment.

It should be noted that the description of “first”, “second” and the like in the present application is only used for description purposes, and cannot be understood as indicating or implying its relative importance or implying the number of indicated technical features. Thus, a feature defined as “first” or “second” may include at least one such feature, either explicitly or implicitly. In addition, the technical solutions among the various embodiments can be combined with each other, but it must be based on that it can be realized by ordinary technicians. When the combination of the technical solutions is contradictory or cannot be realized, it should be considered that the combination of the technical solutions does not exist, nor is it within the scope of protection required by the present application.

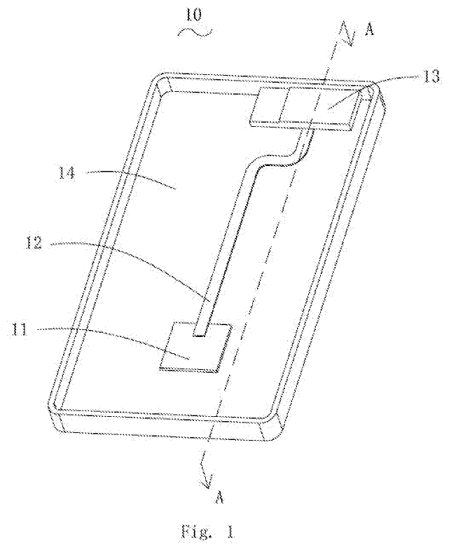

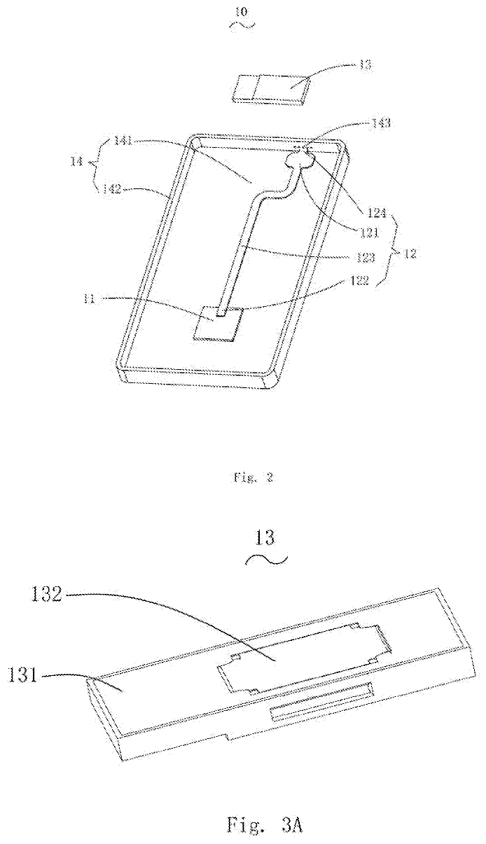

Referring to FIG. 1 and FIG. 2 together, the present invention provides a heat dissipation device 10. In the present invention, the heat dissipation device 10 can be a heat dissipation device such as a mobile phone or a computer. The heat dissipation device 10 comprises a heating element 11, a heat conductor 12, a speaker assembly 13, and a chassis 14. The heat conductor 12 is in contact with the heating element 11 and the speaker assembly 13, the heat conductor 12 is also fixedly connected to the chassis 14. The heat conductor 12 is used for guiding the heat generated by the heating element 11 to the speaker assembly 13, and when the speaker assembly 13 vibrates, the air can be driven to transfer the heat quickly. The heat dissipation of the heat dissipation device 10 can be accelerated, and the operation temperature of the heat dissipation device 10 is lowered, so that the heat dissipation device 10 can work stably.

The heating element 11 is an element that generates heat in the heat dissipation device 10, and the heating element 11 may be a control module of the heat dissipation device 10, such as a CPU (Central Processing Unit) of the heat dissipation device 10, the heating element 11 can also be a battery for the heat dissipation device 10. It will be understood that the heating element 11 is not limited to the two components listed in this embodiment, but can generate heat.

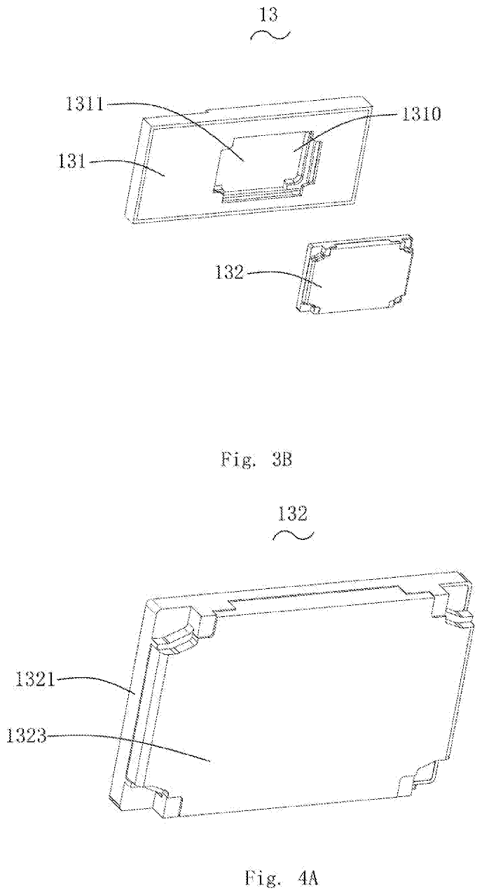

Referring to FIGS. 3A and 3B, the speaker assembly 13 comprises a housing 131 having an accommodation space 1310 and a speaker unit 132 installed in the accommodation space 1310. The housing 131 is arranged with an opening 1311, and the speaker unit 132 is exposed at the housing 131 via the opening 1311. Preferably, the heat conductor 12 is also in contact with and fixedly connected to the housing 131.

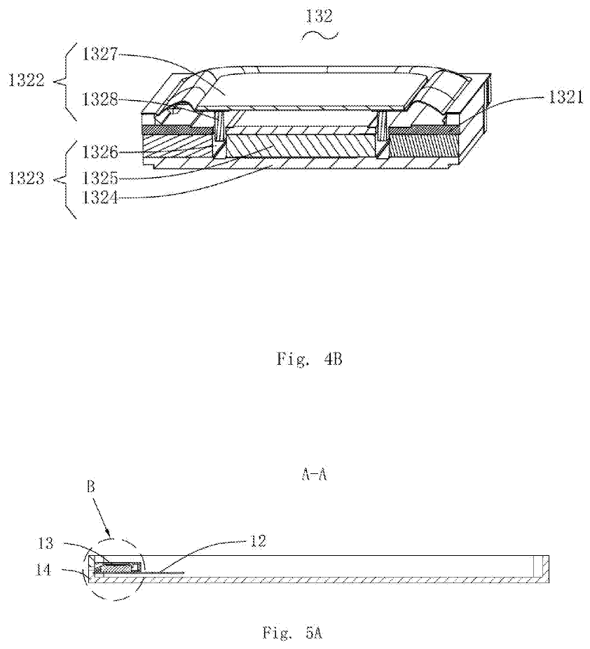

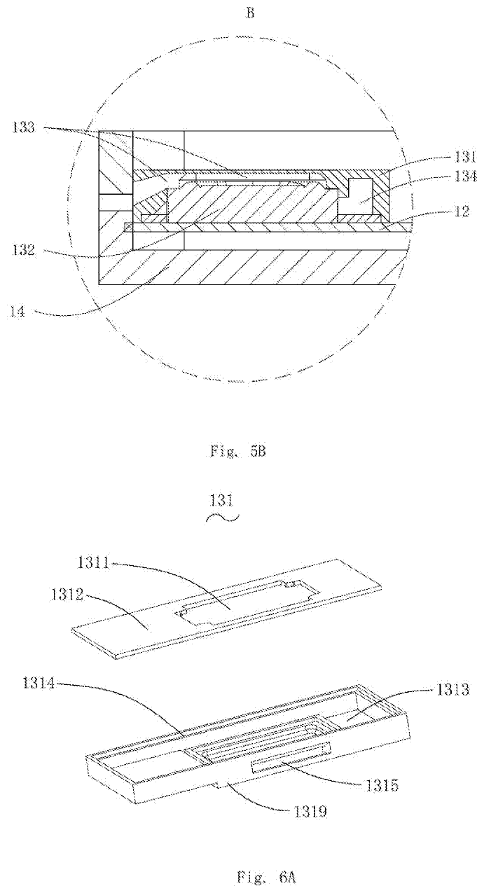

Referring to FIGS. 4A, 4B, 5A, and 5B together, the speaker unit 132 comprises a pot holder 1321, a vibration system 1322 fixed on the pot holder 1321 and a magnetic circuit system 1323 that drives the vibration system 1322 to vibrate.

The side of the magnetic circuit system 1323 away from the vibration system 1322 is arranged at least partially exposed at the housing 131. Specifically, the magnetic circuit system 1323 is exposed at the housing 131 via the opening 1311. A magnetic circuit system 1323 comprise a yoke 1324 and a magnet assembly 1325 fixed to one side of that yoke 1324 near the vibration system 1322. The magnetic circuit system 1323 is provided with a magnetic gap 1326. The yoke 1324 is exposed at the pot holder 1321, i.e., the yoke 1324 is exposed at the surface of the housing 131. The yoke 1324 is a part of the surface of the speaker unit 132. Yoke 1324 is made of magnetic conductive material, which is used to form uniform magnetic field and improve the electromagnetic induction performance of products. The yoke 1324 is arranged at least partially exposed at the housing 131 via the opening 1311. The outer surface of the yoke 1324 and the outer surface of the housing 131 are coplanar. The yoke 1324 is in contact with the heat conductor 12, the heat conductor 12 guides the heat generated by the heating element 11 to the yoke 1324 of the speaker assembly, then the yoke 1324 further radiates the heat into the speaker assembly 13.

The vibration system 1322 comprises a diaphragm 1327 and a voice coil 1328 that drives the diaphragm 1327 to vibrate. The voice coil 1328 is inserted into the magnetic gap 1326, and the voice coil 1328 drives the diaphragm 1327 to vibrate and sound during powering up of the voice coil 1328. The vibration system 1322 separates the accommodation space 1310 into a front cavity 133 and a back cavity 134.

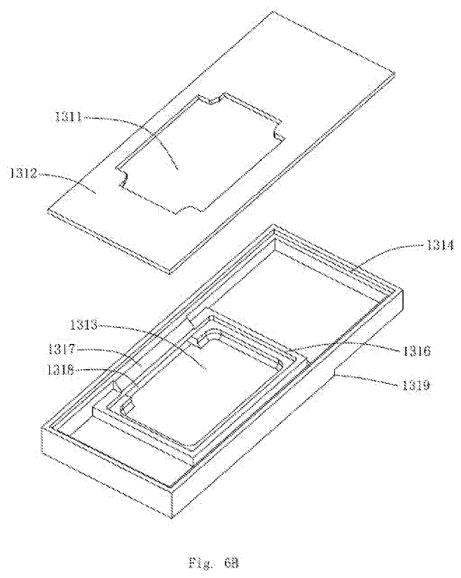

Referring to FIGS. 6A and 6B, the housing 131 comprises a top wall 1313 arranged opposite to the vibration system 1322, a bottom wall 1312 fixed to the magnetic circuit system 1323, and a side wall 1314 bending and extending from the edge of the top wall 1313 in a direction close to the bottom wall 1312. The top wall 1313, the side wall 1314 and the bottom wall 1312 enclose to form the accommodation space 1310. The opening 1311 is arranged in the bottom wall 1312. When the speaker unit 132 is fixed in the accommodation space 1310, the yoke 1324 is arranged at least partially exposed at the bottom wall 1312 via the opening 1311. The outer surface of the yoke 1324 and the outer surface of the bottom wall 1312 are coplanar. The heat conductor 12 contacts with the yoke 1324 and the bottom wall 1312 at the same time, and the heat conductor 12 is also fixed on the bottom wall 1312.

The side wall 1314 of the housing 131 is arranged with a sound outlet hole 1315 which communicates the front cavity 133 with the outside. The sound outlet hole 1315 enables the sound of the speaker unit 132 to be transferred out, and the speaker assembly 13 can transfer heat out of the sound outlet hole 1315 with the vibration of the air in the front cavity 133.

The housing 131 also comprises a support wall 1316 that extends from the top wall 1313 into the accommodation space 1310 and supports the speaker unit 132.

The housing 131 also comprises a barrier wall 1317 extending from the side wall 1314 toward the speaker unit 132. A sound channel 1318 is enclosed between the barrier wall 1317 and the top wall 1313 as well as the side wall 1314. A front cavity is formed between the diaphragm 1327 and the top wall 1313 facing the diaphragm 1327. The front cavity 133 comprises the front cavity and the sound channel 1318. The sound channel 1318 communicates the front acoustic cavity with the sound outlet hole 1315.

The housing 131 also comprises a metal embedding member 1319 embedded in the top wall, and the metal embedding member 1319 directly faces the diaphragm 1327 and is integrally molded with the top wall 1313.

Referring to FIG. 2, the chassis 14 comprises a bottom panel 141 arranged opposite to the bottom wall 1312 of the housing 131 and a side panel 142 bending and extending from the edge of the bottom panel 141. The side panel 142 is attached to one side of the side wall 1314 of the housing 131 on which the sound outlet hole 1315 is opened correspondingly. The side panel 142 is correspondingly provided with a through hole 143 that connects the sound outlet hole 1315 with the outside. Preferably, the bottom panel 141 and the side panel 142 are integrally formed. The chassis 14 can be made of metal, alloy or plastic, for example, the chassis 14 can be made of aluminum alloy chassis. The speaker unit 132 emits sound via the sound outlet hole 1315, which then passes through the sound hole 141 of the chassis 14 and is sent out from inside the heat dissipation device 10.

Referring to FIG. 2, the heat conductor 12 is an element in the heat dissipation device 10 for transferring heat, or the heat conductor 12 is an element that has a cooling effect. The heat conductor 12 is used to guide the heat generated by the heating element 11 to the speaker assembly 13 and transfer it with the air in the front cavity 133 to the outside of the sound outlet hole 1315. The heat conductor 12 is strip-shaped, and the width L of the part where the heat conductor 12 and the yoke 1324 are connected in the direction perpendicular to the axial direction thereof as shown in the figure is larger than the width of other parts of the heat conductor 12. The heat conductor 12 comprises a first end part 121 which is fixed to the yoke 1324 of the side of the magnetic circuit system 1323 away from the vibration system 1322, a second end part 122 connected to the heating element 11 and a connection part 123 connecting the first end part 121 and the second end part 122; the heat conductor 12 also comprises an extension part 124 extending from the first end part 121 toward the side panel 142. Wherein, the first end part 121 is sandwiched between the bottom plate 141 and the speaker assembly 13, and the side of the extension part 124 away from the first end part 121 is embedded in the side panel 142. The side of the connection part 123 near the first end part 121 is fixedly connected to the outer surface of the bottom wall 1312 of the housing 131. The extension part 124 is embedded in the chassis 14, and since the chassis 14 dissipates heat quickly, the heat dissipation of the heat dissipation device 10 can also be accelerated.

In particular, the heat conductor 12 may be a metal sheet or a hollow heat pipe containing a condensed liquid inside. The metal sheet has a good heat conductivity, and can transfer away the heat of heating element 11 and speaker assembly 13 quickly, so as to reduce the temperature of the heating element 11 and the speaker assembly 13. The metal sheet can be copper sheet or aluminum sheet, etc. The heat pipe can be an existing heat pipe. The heat pipe comprises a pipe shell, a liquid absorbing core and an end cover. The inside of the pipe shell is pumped into an appropriate negative pressure and then filled with an appropriate amount of working liquid, so that the capillary porous material of the liquid absorbing core closely attached to the inner wall of the pipe shell is filled with liquid, and then is sealed with the end cover.

One end of the heat pipe is an evaporation section and the other end is a condensation section. When one end of the heat pipe is heated, the liquid in liquid absorbing core evaporates and vaporizes, the steam flows to the condensation section under a small pressure difference and releases heat to condense into liquid, which flows back to the evaporation section along the porous material of the liquid absorbing core by capillary force. In such continuous cycles, the heat is transferred from the evaporation section to the condensation section of the heat pipe. The evaporation section of the heat pipe is in contact with the heating element 11, and the condensation section of the heat pipe is connected to the chassis 14.

When it is used, the speaker unit 132 of the speaker assembly 13 may input a pulse signal of a relatively low frequency (e.g. less than 1000 Hz) while the speaker assembly 13 is performing heat dissipation work, to drive the diaphragm 1327 of the drive speaker unit 132 to vibrate, pushing the front cavity 133 air flow to form the air cooling effect, so as to transfer the heat guided to the speaker assembly 13 by the heat conductor 12 to the outside of the sound outlet hole 1315 with the air in the front cavity 133.

When the speaker unit 132 is not performing a music playback task, the pulse signal of a lower frequency can be played separately; when performing the music playing task, the pulse signal of a lower frequency can be superimposed into the music signal. Because the pulse signal of the lower frequency is lower than 1000 Hz, it will not be heard by human ears and does not affect the normal listening effect.

Compared with the prior art, in the embodiment of the invention, the heat conductor can guide the heat generated by the heating element to the speaker assembly and transfer the heat to the outside of the sound outlet hole along with the air in the front cavity, so that the speaker assembly can play the role of air cooling, effectively reduce the working temperature of the heating element, make the heat dissipation device work stably with a good cooling effect, and improve the life of the heat dissipation device.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A heat dissipation device, the heat dissipation device comprising:
a heating element; and
a speaker assembly comprising a housing having an accommodation space, and a speaker unit installed in the accommodation space and comprising a vibration system and a magnetic circuit system that drives the vibration system to vibrate; at least part of one side of the magnetic circuit system away from the vibration system exposed at the housing via an opening in the housing; the vibration system separating the accommodation space into a front cavity and a back cavity;
a sound outlet hole arranged in the housing for connecting the front cavity and outside;
a heat conductor comprising a first end part fixed to a side of the magnetic circuit system away from the vibration system, a second end part connected to the heating element, a connection part connecting the first end part and the second end part, for introducing the heat generated by the heating element to the speaker assembly and then transfer to the outside of the sound outlet hole with air in the front cavity.

2. The heat dissipation device as described in claim 1, wherein the housing comprises a top wall arranged opposite to the vibration system, a bottom wall fixed to the magnetic circuit system, and a side wall bending and extending from the edge of the top wall to a direction close to the bottom wall; the top wall, the side wall and the bottom wall enclose to form the accommodation space; the opening is arranged on the bottom wall; the housing further comprises a support wall extending from the top wall into the accommodation space and supporting the speaker unit.

3. The heat dissipation device as described in claim 2, wherein the magnetic circuit system comprises a yoke and a magnet assembly fixed to one side of the yoke near the vibration system, at least part of the yoke is arranged exposed at the bottom wall via the opening.

4. The heat dissipation device as described in claim 3, wherein an outer surface of the yoke and an outer surface of the bottom wall are coplanar, and one side of the connection part near the first end part is fixedly connected to the outer surfaces of the housing.

5. The heat dissipation device as described in claim 2, wherein the sound outlet hole is arranged on the side wall, and the housing further comprises a baffle wall extending from the side wall toward the speaker unit, a sound channel is enclosed and formed between the baffle wall and the top wall as well as the side wall; the vibration system comprises a diaphragm, and the front acoustic cavity is formed between the diaphragm and the top wall directly facing the diaphragm; the front cavity comprises the front acoustic cavity and the sound channel, the sound channel communicates the front acoustic cavity with the sound outlet hole.

6. The heat dissipation device as described in claim 5, wherein the housing further comprises a metal embedding member embedded in the top wall, the metal embedding member is directly facing the diaphragm and integrally formed with the top wall by injection molding.

7. The heat dissipation device as described in claim 2, wherein the heat dissipation device further comprises a chassis, the chassis comprises a bottom plate arranged opposite to the bottom wall and a side panel bending and extending from the edge of the bottom plate, the first end part is sandwiched between the bottom plate and the speaker assembly, the side panel is attached to one side of the side wall correspondingly arranged with the sound outlet hole, the side panel is correspondingly arranged with a through hole communicating the sound outlet hole and the outside.

8. The heat dissipation device as described in claim 7, wherein the heat conductor further comprises an extension part extending from the first end part toward the side panel, the side of the extension part away from the first end part is embedded in the side panel.

9. The heat dissipation device as described in claim 7, wherein the bottom plate and the side panel are integrally formed.

10. The heat dissipation device as described in claim 1, wherein the heat conductor is a heat conducting tube or a solid metal conductor with a condensed liquid inside.

11. The heat dissipation device as described in claim 1, wherein the heat conductor is strip-shaped, and the width of the first end part is larger than the width of other parts of the heat conductor.
